(19) United States
(12) Patent Application Publication
(10) Pub. No.: US 2009/0098735 A1
(43) Pub. Date: Apr. 16, 2009

(54) METHOD OF FORMING ISOLATION LAYER IN SEMICONDCUTOR DEVICE

(76) Inventor: Eun-Sang Cho, Seongnam (KR)

Correspondence Address: SHERR & VAUGHN, PLLC, 620 HERNDON PARKWAY, SUITE 200, HERNDON, VA, 20170, US

(21) Appl. No.: 12/241,127

(22) Filed: Sep. 30, 2008

(30) Foreign Application Priority Data
Oct. 10, 2007 (KR) 10-2007-0102125

(51) Int. Cl. H01L 21/311

(52) U.S. Cl. 438/703; 257/E21.249

(57) ABSTRACT

A method of forming an isolation layer in a semiconductor device which prevents formation of voids in the isolation layer by sequentially forming an insulating layer and an anti-reflective layer on and/or over a semiconductor substrate, and then forming a photoresist pattern on and/or over the anti-reflective layer, and then forming an insulating layer pattern on and/or over and corresponding to an isolation area of the substrate by performing an etch process using the photoresist pattern as an etch mask, and then forming a polysilicon layer around the insulating layer pattern such that the insulating layer patterns protrudes from the uppermost surface of the polysilicon layer.

The present application claims priority under 35 U.S.C. §119 to Korean Patent Application No. 10-2007-0102125 (filed on Oct. 10, 2007), which is hereby incorporated by reference in its entirety.

### BACKGROUND

Generally, an isolation layer is formed to discriminate or otherwise define active and inactive areas in a semiconductor device. One method of forming an isolation layer includes shallow trench isolation (STI). In STI, a shallow trench is formed in a semiconductor substrate and is then filled up with an insulating material.

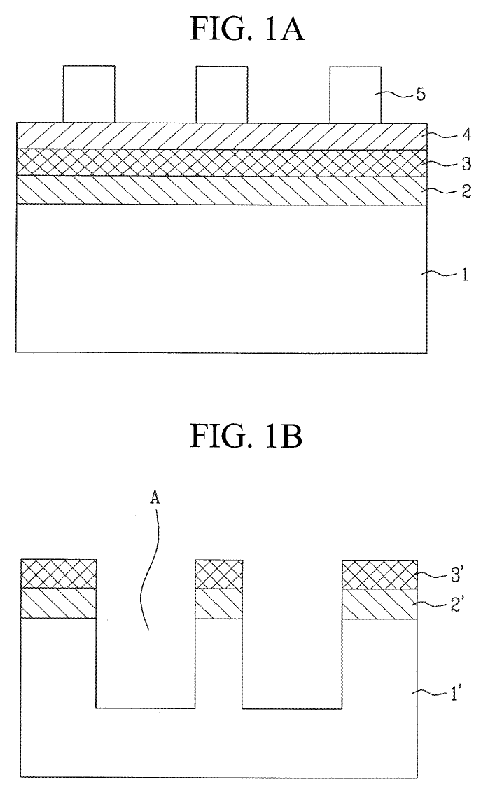

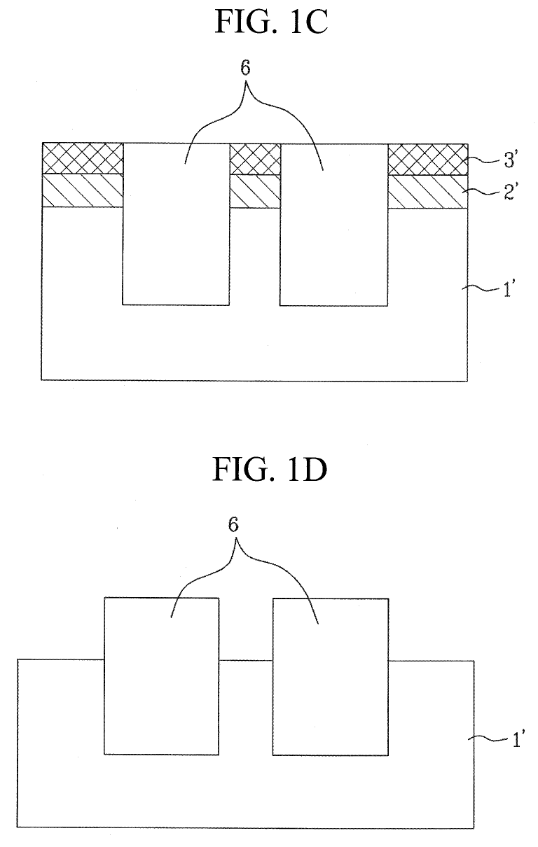

As illustrated in example FIG. 1A, a method of forming an isolation layer in a semiconductor device may include sequentially forming silicon nitride layer 2, silicon oxide layer 3 and bottom anti-reflective coating (BARC) layer 4 on and/or over semiconductor substrate 1. Silicon nitride layer 2 and silicon oxide layer 3 are formed by chemical vapor deposition (CVD). Photoresist pattern 5 is then formed on and/or BARC 4. Photoresist pattern 5 is provided to discriminate an active area and an inactive area that will be formed on and/or over substrate 1. Photoresist pattern 5 is formed to correspond to the active area in which a prescribed semiconductor device including a transistor will be formed.

As illustrated in example FIGS. 1B to 1D, an etch process is performed using photoresist pattern 5 as an etch mask until a surface of substrate 1 is exposed. BARC layer 4, silicon oxide layer 3 and silicon nitride layer 2 are partially removed by the etch process. Subsequently, using the etched silicon oxide layer 3′ and silicon nitride layer 2′ remaining after the etch process as an etch mask, the exposed surface of substrate 1 is etched to form trench (A) in substrate 1. As illustrated in example FIG. 1C, trench (A) is then filled up with oxide layer 6. Optionally, a liner oxide layer can be formed by performing oxidation on a sidewall and bottom of the trench before the trench is filled with the oxide layer. As illustrated in example FIG. 1D, silicon oxide layer 3′ and silicon nitride layer 2′ are then removed from substrate 1.

As semiconductor devices become more highly integrated and downsized, a gap between transistors provided in the semiconductor device is reduced. Accordingly, power used per unit area increases while a width of STI for an isolation layer between the transistors decreases. Therefore, the demand for fine patterning and oxide gap-fill technologies rises. In such a STI forming method, the fine patterning technology is freely applicable to devices up to 65 nm scale using ArF light source. Yet, as semiconductor devices are further reduced in size, a gap of trench to be filled decreases while a depth thereof increases. Therefore, in case of filling the trench with an insulating layer, voids may be generated in the insulating layer.

### SUMMARY

Embodiments relate to a method of forming an isolation layer in a semiconductor device that prevents void generation in the isolation layer.

Embodiments relate to a method of forming an isolation layer in a semiconductor device which prevents formation of voids in the course of filling a trench with an insulating layer.

Embodiments relate to a method of forming an isolation layer in a semiconductor device that may include at least one of the following steps: sequentially forming an insulating layer and an anti-reflective layer on and/or over a semiconductor substrate; and then forming a photoresist pattern on and/or over the anti-reflective layer; and then forming an insulating layer pattern on and/or over an isolation area by performing an etch process using the photoresist pattern as an etch mask; and then forming a polysilicon layer around the insulating layer pattern.

Embodiments relate to a method of forming an isolation layer in a semiconductor device that may include at least one of the following steps: sequentially forming an insulating layer and an anti-reflective layer over a semiconductor substrate having an isolation area for defining an active region; and then forming a photoresist pattern over the anti-reflective layer; and then forming an insulating layer pattern over the isolation area by performing an etch process using the photoresist pattern as an etch mask; and then forming a polysilicon layer around the insulating layer pattern.

Embodiments relate to a method that may include at least one of the following steps: sequentially forming an insulating layer, an anti-reflective layer and photoresist layer over a semiconductor substrate having an isolation region; and then forming a photoresist pattern corresponding spatially to the isolation region by patterning the photoresist layer; and then forming an insulating layer pattern in the isolation region by performing a first etching process using the photoresist pattern as an etching mask; and then forming a polysilicon layer over the semiconductor substrate to surround the insulating layer pattern such that a portion of the insulating layer pattern protrudes from the uppermost surface of the polysilicon layer.

Embodiments relate to a method that may include at least one of the following steps: sequentially forming an insulating layer and an anti-reflective layer over a semiconductor substrate having an isolation region; and then forming photoresist patterns over the anti-reflective coating layer corresponding spatially to the isolation region; and then forming insulating layer patterns in the isolation region by performing a first etching process using the photoresist patterns as etching masks; and then forming a polysilicon layer over the semiconductor substrate such that the uppermost surface of the polysilicon layer is on a plane spatially below the plane of the uppermost surface of the insulating layer patterns; and then bonding the polysilicon layer to the semiconductor substrate at an interface therebetween.

### DRAWINGS

Example FIGS. 1A to 1D illustrate a method of forming an isolation layer in a semiconductor device.

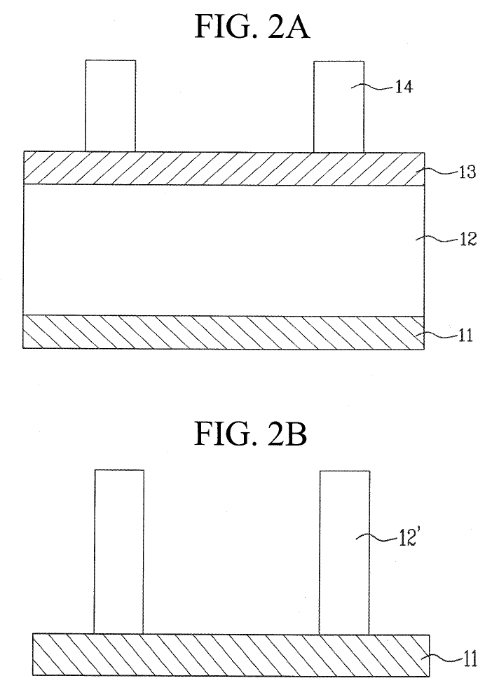

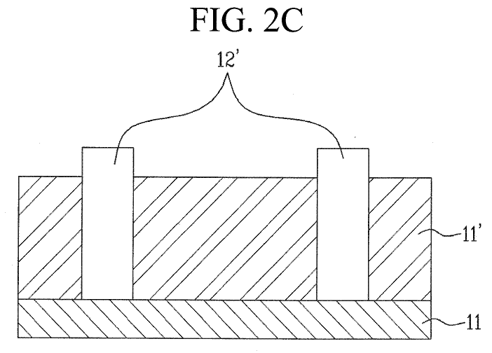

Example FIGS. 2A to 2C illustrate a method of forming an isolation layer in a semiconductor device in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

As illustrated in example FIG. 2A, insulating layer 12 and anti-reflective layer 13 are sequentially formed on and/or over semiconductor substrate 11. Photoresist pattern 14 is then formed on and/or over anti-reflective layer 13. Anti-reflective layer 13 is provided to prevent diffused reflection and preferably includes a bottom anti-reflective coating (BARC) layer. Anti-reflective layer 13 is formed by coating. Insulating layer 12 includes a silicon oxide layer and is formed by chemical vapor deposition (CVD). Photoresist pattern 14 is provided to form an isolation layer for defining an active area and an inactive area from each other. Photoresist pattern 14 is formed on and/or over an isolation area for forming the isolation layer. Particularly, photoresist pattern 14 is formed to spatially correspond to the inactive area where the isolation layer will be formed.

As illustrated in example FIG. 2B, subsequently, using photoresist pattern 14 as an etch mask, an etch process is performed until portions of the surface of substrate 11 are exposed. Hence, insulating layer pattern 12′ is formed. Although photoresist pattern 14 plays a role as a mask for the etch process, photoresist pattern 14 as well as anti-reflective layer 13 is removed while a portion of insulating layer 12 is partially removed. Alternatively, by performing a first etch process using photoresist pattern 14 as an etch mask until portions of substrate 11 are exposed, insulating layer 12 and anti-reflective layer 13 are selectively etched. Subsequently, a second etch process can be performed to remove photoresist pattern 14 and anti-reflective layer 13 remaining after the first etch process. Through the two etching processes, insulating layer pattern 12′ may be formed.

As illustrated in example FIG. 2C, thereafter, polysilicon is deposited on and/or over substrate 11 including insulating layer pattern 12′ to thereby form polysilicon layer 11′ around insulating layer pattern 12′. Polysilicon layer 11′ is formed by CVD. Polysilicon layer 11′ is deposited to have a height lower than that of insulating layer pattern 12′. As a stack coverage of polysilicon layer 11′ is higher than that of the oxide layer, it is much less probable that void may be generated in the course of forming the isolation layer. Subsequently, annealing is performed on and/or over the entire substrate 11 to enable polysilicon layer 11′ and substrate 11 to be stably attached together.

As mentioned herein, a method of forming an isolation layer in a semiconductor device in accordance with embodiments can prevent voids from forming in an isolation layer by filling a trench with an oxide material. Namely, by forming an isolation layer in a manner of depositing polysilicon having stack coverage higher than that of the oxide, it is much less probable that voids may be generated in the course of forming the isolation layer.

An isolation layer is formed in a manner of forming a trench by etching an inactive area portion located on a boundary between an active area and the inactive area and then filling the trench with an insulating layer. Yet, embodiments exclude the trench forming concept. In particular, instead of forming a trench by etching, an insulating layer pattern is formed on and/or over a substrate by etching and such a substance of the substrate as polysilicon is then deposited around the insulating layer pattern. Therefore, the insulating pattern plays a role as a single isolation layer.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming an isolation layer in a semiconductor device comprising:
sequentially forming an insulating layer and an anti-reflective layer over a semiconductor substrate having an isolation area for defining an active region; and then
forming a photoresist pattern over the anti-reflective layer; and then
forming an insulating layer pattern over the isolation area by performing an etch process using the photoresist pattern as an etch mask; and then
forming a polysilicon layer around the insulating layer pattern.

2. The method of claim 1, wherein the insulating layer comprises a silicon oxide layer.

3. The method of claim 2, wherein the silicon oxide layer is deposited by chemical vapor deposition (CVD).

4. The method of claim 1, wherein the anti-reflective layer comprises a bottom anti-reflective coating layer.

5. The method of claim 1, wherein forming the insulating layer pattern comprises selectively etching the anti-reflective layer and the insulating layer using the photoresist pattern as an etch mask until the semiconductor substrate is exposed.

6. The method of claim 5, wherein during the selective etching, portions of the photoresist pattern and the anti-reflective layer are removed over the insulating layer pattern.

7. The method of claim 1, wherein forming the polysilicon layer comprises forming the polysilicon layer such that the uppermost surface of the polysilicon layer is on a plane lower than the plane of the uppermost surface of the insulating layer pattern.

8. The method of claim 1, wherein forming the polysilicon layer comprises forming the polysilicon layer such that a portion of the insulating layer pattern protrudes from the polysilicon layer.

9. The method of claim 1, further comprising, after forming the polysilicon layer: performing an annealing process on the entire semiconductor substrate.

10. A method comprising:
sequentially forming an insulating layer, an anti-reflective layer and photoresist layer over a semiconductor substrate having an isolation region; and then
forming a photoresist pattern corresponding spatially to the isolation region by patterning the photoresist layer; and then
forming an insulating layer pattern in the isolation region by performing a first etching process using the photoresist pattern as an etching mask; and then
forming a polysilicon layer over the semiconductor substrate to surround the insulating layer pattern such that a portion of the insulating layer pattern protrudes from the uppermost surface of the polysilicon layer.

11. The method of claim 10, wherein the insulating layer comprises a silicon oxide layer.

12. The method of claim 11, wherein the silicon oxide layer is deposited by chemical vapor deposition (CVD).

13. The method of claim 10, wherein forming the insulating pattern comprises exposing the uppermost surface of the semiconductor substrate.

14. The method of claim 10, wherein forming the insulating pattern comprises:
removing the photoresist pattern and the anti-reflective layer while removing a portion of the insulating layer.

15. The method of claim 10, wherein forming the insulating pattern comprises:
performing the first etching process to etch protons of the insulating layer and the anti-reflective layer using the photoresist pattern as an etch mask until portions of the semiconductor substrate are exposed; and then
performing a second etching process to remove the photoresist pattern and the anti-reflective layer remaining after the first etch process.

16. The method of claim 10, further comprising, after forming the polysilicon layer: bonding the polysilicon layer to the semiconductor substrate at an interface therebetween.

17. The method of claim 10, wherein bonding the polysilicon layer to the semiconductor substrate comprises performing an annealing process.

18. A method comprising:
sequentially forming an insulating layer and an anti-reflective layer over a semiconductor substrate having an isolation region; and then
forming photoresist patterns over the anti-reflective coating layer corresponding spatially to the isolation region; and then
forming insulating layer patterns in the isolation region by performing a first etching process using the photoresist patterns as etching masks; and then
forming a polysilicon layer over the semiconductor substrate such that the uppermost surface of the polysilicon layer is on a plane spatially below the plane of the uppermost surface of the insulating layer patterns; and then
bonding the polysilicon layer to the semiconductor substrate at an interface therebetween.

19. The method of claim 18, wherein bonding the polysilicon layer to the semiconductor substrate comprises performing an annealing process.

20. The method of claim 18, wherein the insulating layer comprises silicon oxide.
